(19) United States
(12) Patent Application Publication
(10) Pub. No.: US 2025/0349769 A1
(43) Pub. Date: Nov. 13, 2025

(54) THERMAL PERFORMANCE OF STACKED DIES

(71) Applicant: Taiwan Semiconductor Manufacturing Company, Ltd., Hsin-Chu (TW)

(72) Inventors: Sheng-Han Tsai, Hsinchu (TW); Tsung-Yu Chen, Hsinchu City (TW); Wensen Hung, Hsinchu County (TW); Yen-Pu Chen, Hsinchu (TW)

(21) Appl. No.: 19/280,570

(22) Filed: Jul. 25, 2025

Related U.S. Application Data
(63) Continuation of application No. 18/644,451, filed on Apr. 24, 2024.
(60) Provisional application No. 63/617,162, filed on Jan. 3, 2024.

(51) Int. Cl. H01L 23/00; H01L 25/18; H10B 80/00

(52) U.S. Cl. CPC H01L 24/05; H01L 24/03; H01L 24/13; H01L 24/16; H01L 24/97; H01L 25/18; H10B 80/00; H01L 2224/0345; H01L 2224/05013; H01L 2224/05015; H01L 2224/05022; H01L 2224/05124; H01L 2224/05147; H01L 2224/05666; H01L 2224/13023; H01L 2224/1389; H01L 2224/16227; H01L 2224/97; H01L 2225/107; H01L 2924/1436

(57) ABSTRACT

A semiconductor package according to the present disclosure includes an interposer and a component mounted on the interposer. The component includes a first die and a second die disposed over the first die having a surface away from the first die. The second die includes a metal pad. A top surface of the metal pad is coplanar with the surface. The metal pad is electrically floating.

### PRIORITY DATA

This application is a continuation application of U.S. patent application Ser. No. 18/644,451, filed Apr. 24, 2024, which claims the benefit of U.S. Provisional Application No. 63/617,162, filed Jan. 3, 2024, each of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Besides smaller device dimensions in each generation, packaging technologies have evolved to further boost performance of IC devices. For example, three-dimensional (3D) packaging techniques are introduced to stack multiple IC devices vertically. 3D packaging techniques involve bonding of semiconductor device dies.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method 100 for forming a package structure, according to various aspects of the present disclosure.

FIGS. 2-20 illustrates fragmentary cross-sectional view and a top view of a wafer or a die area of a wafer undergoing various steps of the method 100 in FIG. 1, according to various aspects of the present disclosure.

FIGS. 21-24 illustrate alternative peripheral metal cushion arrangements, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art.

Semiconductor packaging technologies were once just considered backend processes that facilitate chips to interface external circuitry. Times have changed. Computing workloads have evolved so much that brought packaging technologies to the forefront of innovation. Modern packaging provides integration of multiple chips or dies into a single semiconductor device. Depending on the level of stacking, modern semiconductor packages can have a 3D structure. In a 3D packaging structure, at least two dies are stacked one over another. In order to achieve die stacking, dies are thinned down to facilitate through-substrate connections. Warpage of dies has presented challenges in reliable die bonding because warpage may strain or damage the bonding structures. Thinning of the dies further reduces the structural strength of the dies and may aggravate die warpage, which puts on additional strain on bonding integrity. When a heat sink is disposed over the 3D structure, the die on top serves as a heat conduction path to a heat sink for the underlying die. When bonding between two vertically stacked dies is defective, the heat conduction path is disturbed and the thermal resistance is increased. The increase of thermal resistance is undesirable as it impacts satisfactory cooling of the dies.

The present disclosure provides a process to form peripheral metal pads at corners or along edges of a die in a package structure to reduce non-bond situations between two vertically stacked dies and to improve thermal performance. With respect to one or more of dies in a package structure, photolithography and etch processes are employed to form peripheral recesses. After a seed layer is deposited, electrochemical plating techniques are used to deposit a metal layer. A planarization of the metal layer over the peripheral recesses forms peripheral metal pads. The peripheral metal pads are electrically floating and serve to reduce die warpage and provide a high thermal conductivity heat conduction path.

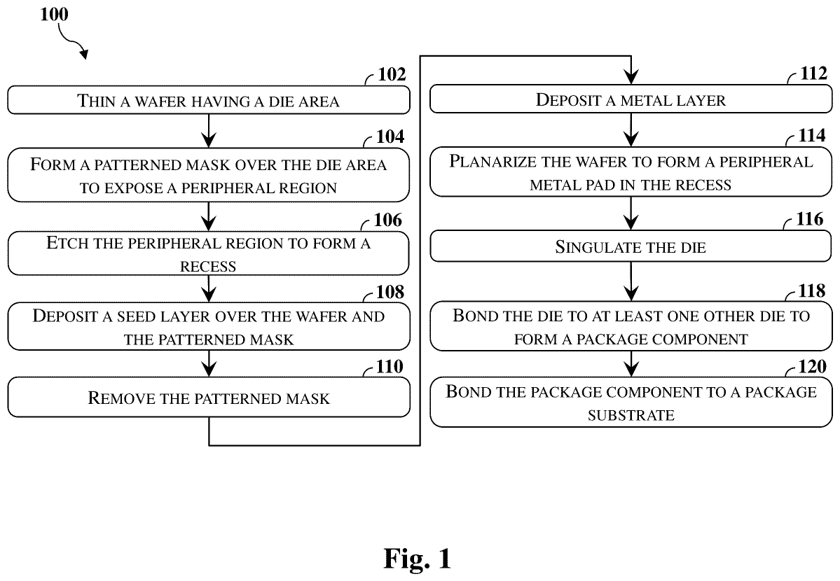

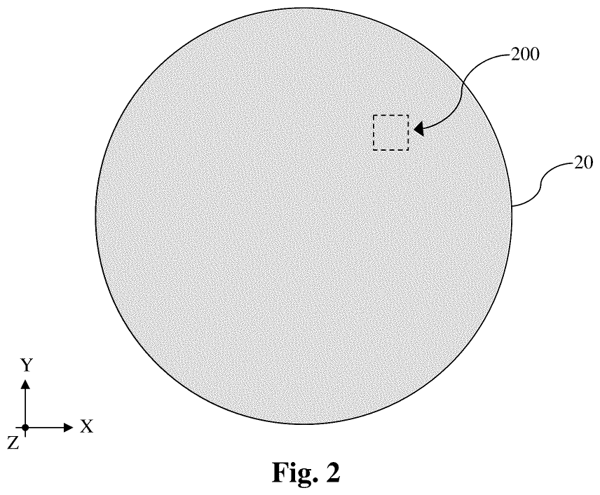

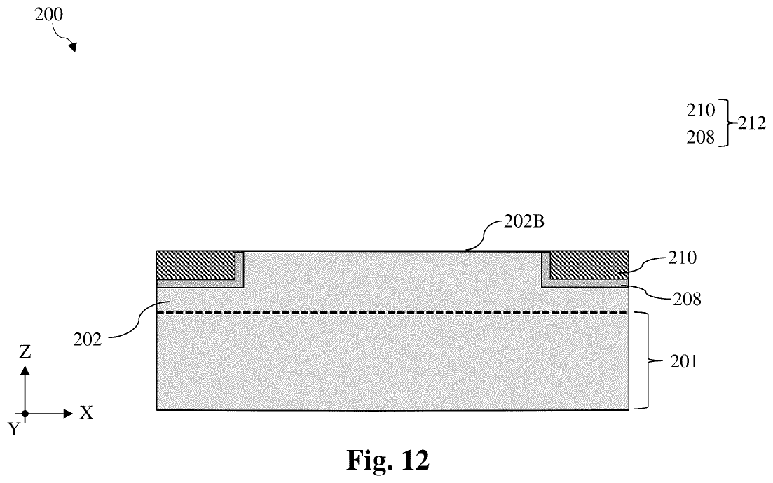

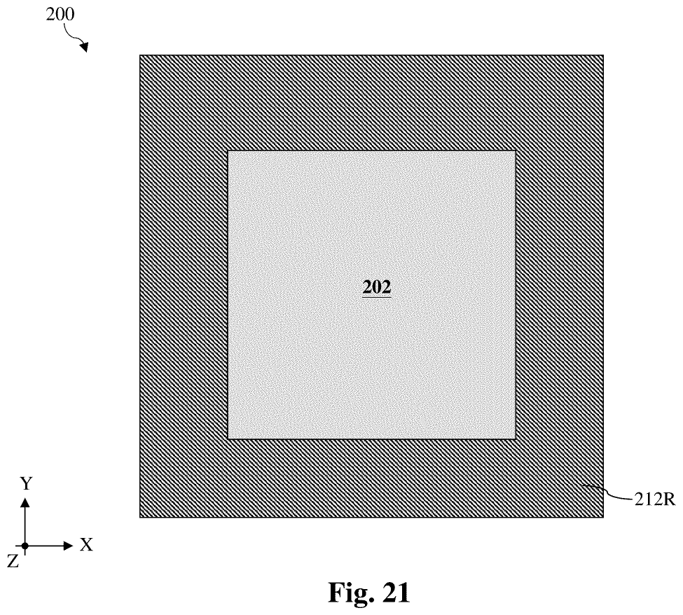

The various aspects of the present disclosure will now be described in more detail with reference to the figures. In that regard, FIG. 1 is a flowchart illustrating method 100 of forming a package structure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIG. 2-20, which are fragmentary cross-sectional views and top views of a wafer, a die area, a package component and a package structure at different stages of fabrication according to various embodiments of method 100. FIGS. 21-24 illustrate alternative embodiments with different peripheral metal pad configurations. For avoidance of doubts, the X, Y and Z directions in FIGS. 2-24, are perpendicular to one another. Throughout the present disclosure, unless expressly otherwise described, like reference numerals denote like features.

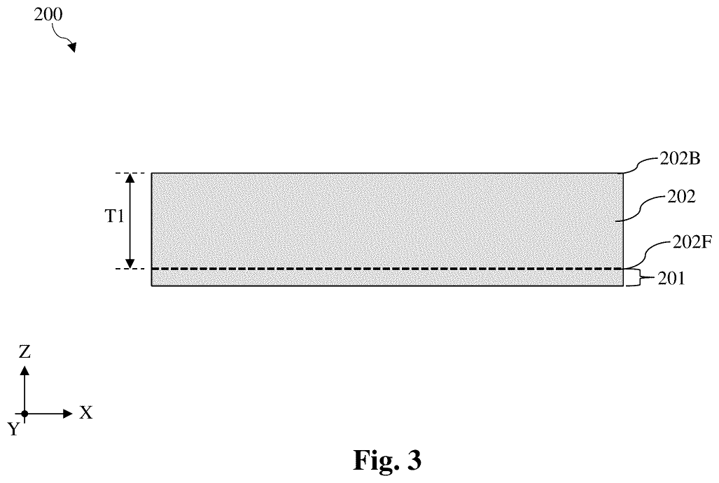

Referring to FIGS. 1 and 2-4, method 100 includes a block 102 where a wafer 20 having a die area 200 is thinned. As illustrated in FIG. 2, the wafer 20 may be circular in shape and have a diameter, such as 200 mm (i.e., 8 inch) or 300 mm (i.e., 12 inch). In some embodiments represented in FIG. 3, the wafer 20 includes a substrate 202 and an interconnect structure 201. The substrate 202 includes a frontside 202F and a back side 202B. The interconnect structure 201 is fabricated over the frontside 202F of the substrate 202. In the depicted embodiments, the wafer 20 has gone through front-end-of-line (FEOL), middle-end-of-line (MEOL), and back-end-of-line (BEOL) processes. As a result, the substrate 202 includes active devices on the frontside 202F. The active devices may include planar devices or multi-gate devices. A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, or other nanostructures and for that reason, a GAA transistor may also be referred to as a nanowire transistor or a nanosheet transistor. The interconnect structure 201 may include 5 to 20 metallization layers. Each of the metallization layers includes metal lines disposed in an intermetal dielectric (IMD) layer. In some embodiments, the interconnect structure 201 has a total thickness smaller than 10 μm. Because the substrate 202 has a thickness in the order of hundreds of micrometers, a thickness of the substrate 202 accounts for the majority of a total thickness of the wafer 20.

The substrate 202 may include silicon(S). Alternatively, the substrate 202 may include other semiconductors such as germanium (SiGe), silicon carbide (SiC), silicon germanium (SiGe), or diamond. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features. While not explicitly shown in the figures, the substrate 202 may include various doping configurations for the formation of the active devices. The doping configurations include n-type wells and p-type wells formed on the wafer 20. N-type wells are doped with an n-type dopant that may include phosphorus (P), arsenide (As), or antimony (Sb). P-type wells are doped with a p-type dopant that may include boron (B) or gallium (Ga). The wells serve to reduce leakage through the substrate. In some instances, n-type active devices are formed over p-type wells and p-type active devices are formed over n-type wells. The suitable doping may be performed using ion implantation of dopants and/or diffusion processes.

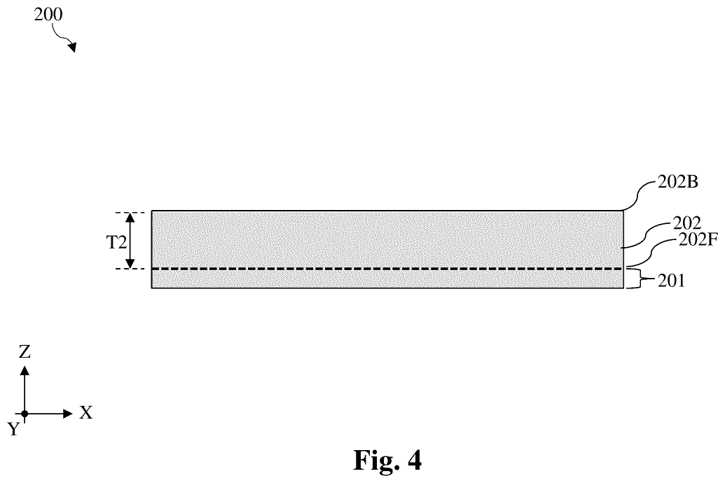

The substrate 202 in the wafer 20 has a first thickness T1. In some instances, the first thickness T1 (shown in FIG. 3) is between about 750 μm and about 800 μm, such as 775 μm. As illustrated in FIG. 2, the wafer 20 includes a plurality of die areas 200. At block 102, as shown in FIG. 4, the back side 202B of the substrate 202 is subject to grinding and polishing steps to have a reduced second thickness T2 smaller than the first thickness T1. The polishing steps at block 102 may include chemical mechanical polishing (CMP). In some embodiments, the second thickness T2 may be between about 300 μm and about 350 μm. The second thickness T2 is smaller than the first thickness T1. In some instances, the second thickness T2 is less than one half of the first thickness T1. For ease of illustration, operations at blocks 104-114 are described below with respect to a die area 200 on the wafer 20 even though these operations are also performed to other die areas of the wafer 20. Because the thickness of the interconnect structure 201 is much smaller than the thickness of the substrate 202, the second thickness T2 is substantially similar to a total thickness of the wafer 20.

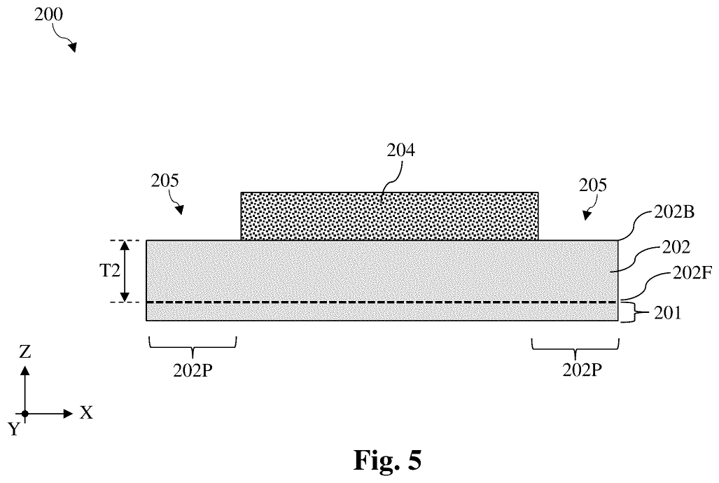

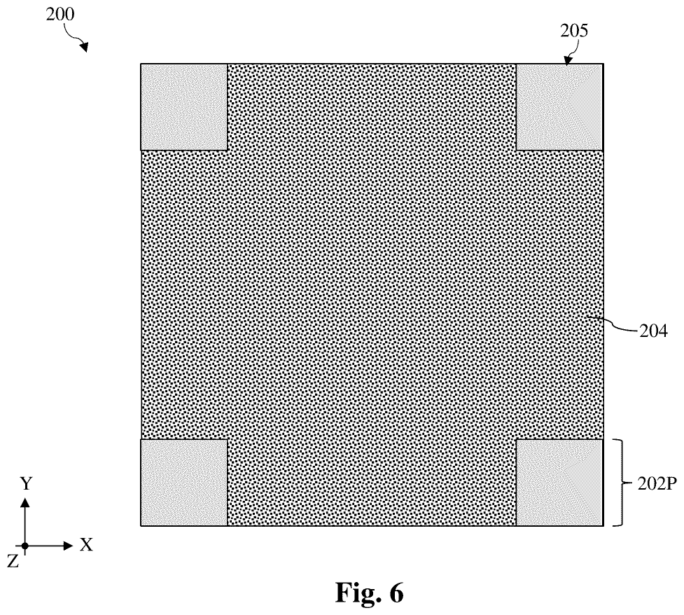

Referring to FIGS. 1 and 5 and 6, method 100 includes a block 104 where a patterned mask 204 is formed over the die area 200 to expose a peripheral region 202P. After the wafer 20 is thinned, a patterned mask 204 is formed over the back side 202B of the thinned substrate 202, as shown in FIG. 5. The patterned mask 204 may include a photoresist. In one embodiment, the photoresist is one that can be removed in a wet chemical stripping process. In an example process, a photoresist layer is deposited over the back side 202B of the substrate 202. After a pre-bake process, the photoresist layer is exposed to radiation going through or reflected from a photomask, baked in a post-bake process, and developed in a developer solution to form a patterned photoresist layer to serve as the patterned mask 204. In the depicted embodiments, the patterned mask 204 includes peripheral opening(s) 205 (or peripheral recess(es) 205) to expose the peripheral regions 202P. In some embodiments illustrated in FIG. 6, each of the peripheral openings 205 is rectangular in shape and is disposed at one of the four (4) corners of the die area 200, which may be rectangular in shape. As will be described further below, in some embodiments, the peripheral opening 205 may extend along the perimeter of the die area to have ring shape. In some other embodiments, each of the peripheral openings 205 may have triangular shape, a circular shape, or a polygonal shape and may occupy one of the four (4) corners of the die area 200.

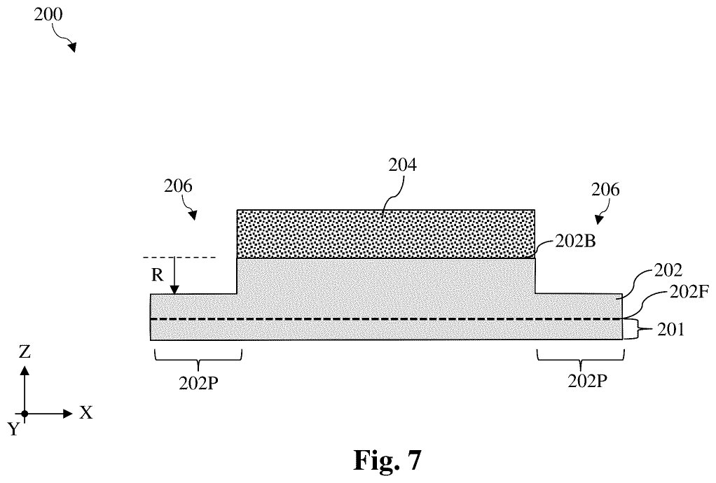

Referring to FIGS. 1 and 7, method 100 includes a block 106 where the peripheral region 202P is etched to form a recess 206. With the patterned mask 204 in place, an anisotropic etch is performed at block 106 to recess the exposed peripheral regions 202P. The anisotropic etch may be a dry etch that implements an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments represented in FIG. 7, the recess 206 formed with the operations at block 106 may have a recess depth R. In some instances, the recess depth R is between about 0.01 (i.e., 1%) and about 0.05 (i.e., 5%) of the second thickness T2 of the thinned substrate 202. That is, a ratio of the depth R and the second thickness T2 is between about 1/100 and about 1/20. In some instances, the depth R may be between about 3 μm and about 15 μm. The shape of the recess 206 generally tracks the shape of the peripheral opening 205. When the peripheral opening 205 is rectangular, the recess 206 is rectangular. When the peripheral opening 205 extends along a perimeter of the back side 202B of the substrate 202, the recess 206 is ring-shaped. When the peripheral opening 205 is circular, triangular or polygonal, the recess 206 may have a circular, triangular or polygonal profile in a top view.

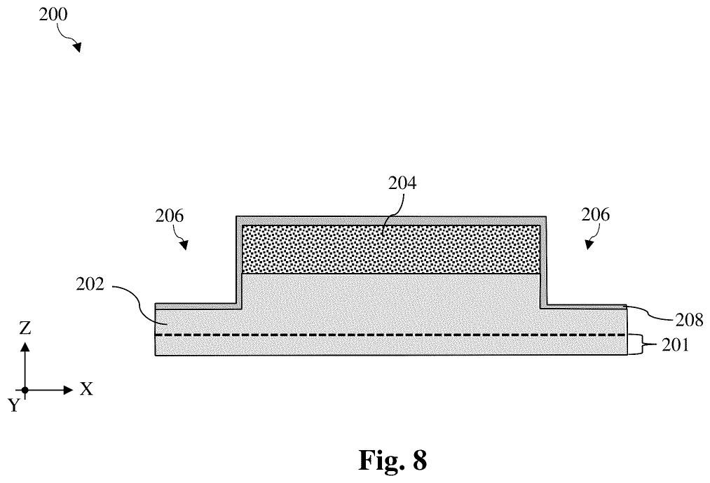

Referring to FIGS. 1 and 8, method 100 includes a block 108 where a seed layer 208 is deposited over the wafer 20 and the patterned mask 204. In some embodiments, the seed layer 208 may include titanium (Ti), copper (Cu), or a combination thereof. In some embodiments, the seed layer 208 is deposited over the back side 202B and the patterned mask 204 using physical vapor deposition (PVD), sputtering, or metalorganic chemical vapor deposition. In one embodiment, the seed layer 208 is deposited by sputtering. In some embodiments, a thickness of the seed layer 208 may be between about 1000 Å and about 3000 Å. As shown in FIG. 8, because the deposition of the seed layer 208 is not selective, it is deposited over not only the peripheral regions 202P but also a top surface and sidewalls of the patterned mask 204.

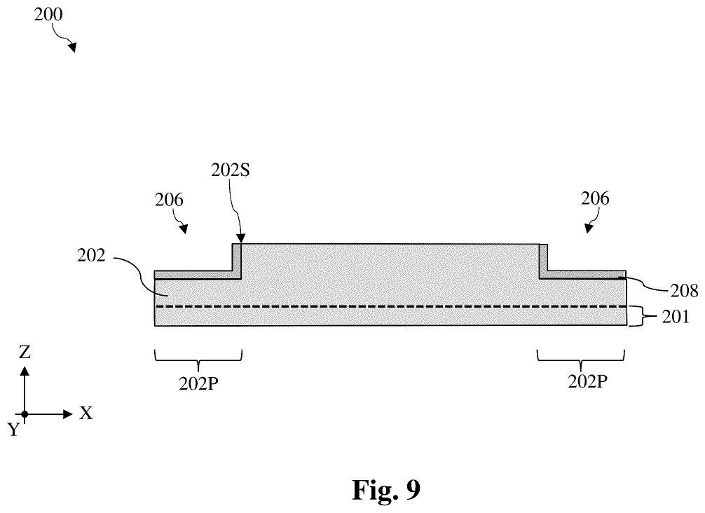

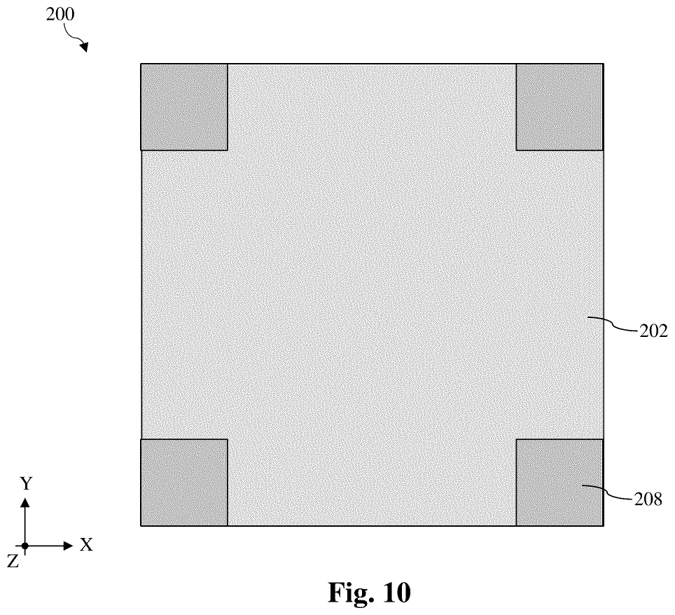

Referring to FIGS. 1 and 9-10, method 100 includes a block 110 where the patterned mask 204 is removed. In some embodiments, the patterned mask 204 is removed by a wet stripping process. An example wet stripping process may include use of a chemical stripper. An example chemical stripper may be a mixture of sulfuric acid and hydrogen peroxide that may be referred to a sulfuric peroxide mixture (SPM). A shown in FIG. 9, the removal of the patterned mask 204 also removes the seed layer 208 deposited along the top surface and sidewalls of the patterned mask 204. As shown in FIGS. 9 and 10, after the patterned mask 204 is removed, the peripheral regions 202P and a sidewall 202S of the substrate 202 exposed in the recesses 206 remain covered by the seed layer 208. This is why, in a cross-sectional view such as the one shown in FIG. 9, the seed layer 208 may have an L-shape profile. The seed layer 208 provides deposition selectivity in the subsequent metal layer deposition process and allows the metal layer deposited thereon to be denser. When the peripheral opening 205 is rectangular, the seed layer 208 in the peripheral regions 202P is rectangular. When the peripheral opening 205 extends along a perimeter of the back side 202B of the substrate 202 to form a ring, the seed layer 208 in the peripheral regions 202P is ring-shaped. When the peripheral opening 205 is circular, triangular or polygonal, the seed layer 208 in the peripheral regions 202P may have a circular, triangular or polygonal profile in a top view.

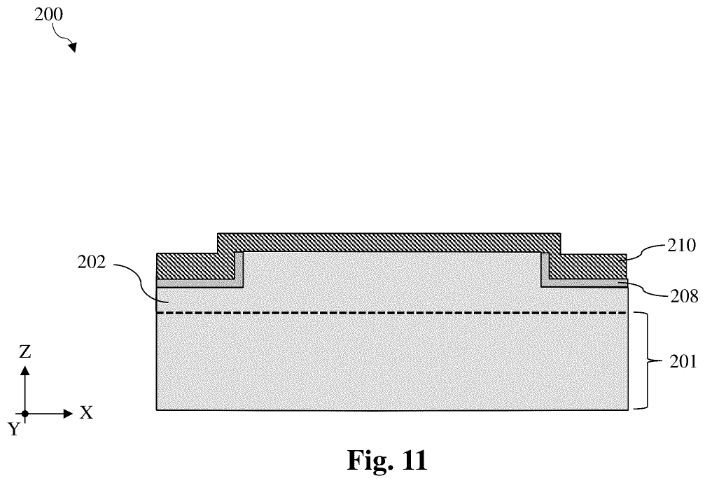

Referring to FIGS. 1 and 11, method 100 includes a block 112 where a metal layer 210 is deposited. In some embodiments, the metal layer 210 includes aluminum (Al), copper (Cu), or aluminum-copper (AlCu). At block 112, an electrochemical plating (ECP) process is used to deposit the metal layer 210. In an example process, the wafer 20 is placed into an electroplating vessel filled with a plating solution. When the metal layer 210 includes copper (Cu), the plating solution may include a mixture of copper salt, acid, water and various organic and inorganic additives that improve the properties of the deposited copper. Suitable copper salts in the plating solution may include copper sulfate, copper cyanide, copper sulfamate, copper chloride, copper formate, copper fluoride, copper nitrate, copper oxide, copper fluorine-borate, copper trifluoroacetate, copper pyrophosphate and copper methane sulfonate, or hydrates of any of the foregoing compounds. The ECP process may last until the metal layer 210 reaches a thickness between 3 μm and about 15 μm. Although ECP preferentially deposits over the seed layer 208, as shown in FIG. 11, a thinner metal layer 210 may be formed over the exposed portion of the substrate 202.

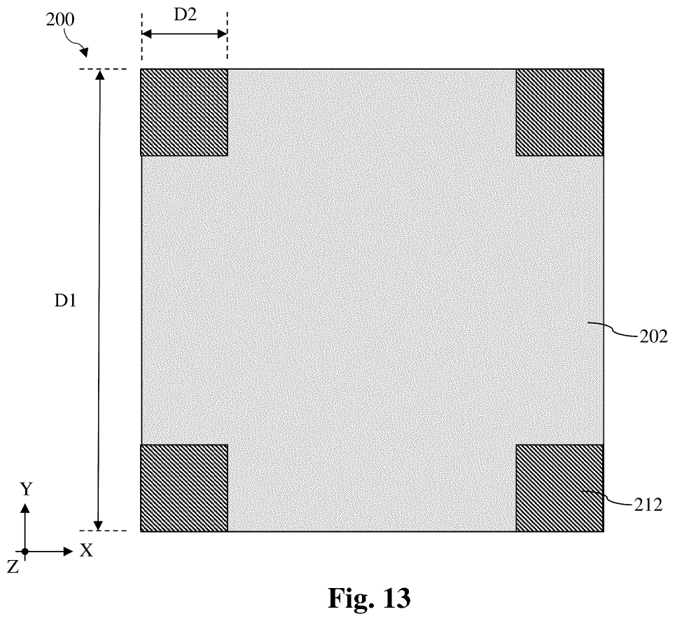

Referring to FIGS. 1 and 12-13, method 100 includes a block 114 where the wafer 20 is planarized to form a peripheral metal pad 212 in the recess 206. At block 114, a chemical mechanical polishing (CMP) process is performed to the wafer 20 to provide a planar surface where top surfaces of the metal layer 210 and the substrate 202 are coplanar. At this point, the planarized metal layer 210 and the underlying seed layer 208 may be collectively referred to as a peripheral metal pad 212 or a cushion pad 212. In some embodiments represented in FIG. 13, each of the peripheral regions 202P is rectangular in shape and the resulting cushion pad 212 is also rectangular in shape. In some instances, the die area 200 is rectangular and has a first edge dimension D1 and each of the rectangular cushion pads 212 may have a second edge dimension D2. The first edge dimension D1 may be between about 5000 μm and about 33000 μm. The second edge dimension D2 is smaller than the first edge dimension D1. The second edge dimension D2 may be between about 20 μm and about 500 μm. It has been observed that a corner non-bond or delamination region may have a dimension around 500 μm. However, to address the corner non-bond conditions, the cushion pad may be a lot smaller. Depending on the design, the exposed back side 202B of the substrate 202 may include a semiconductor material (e.g., silicon) or a dielectric material (e.g., silicon oxide).

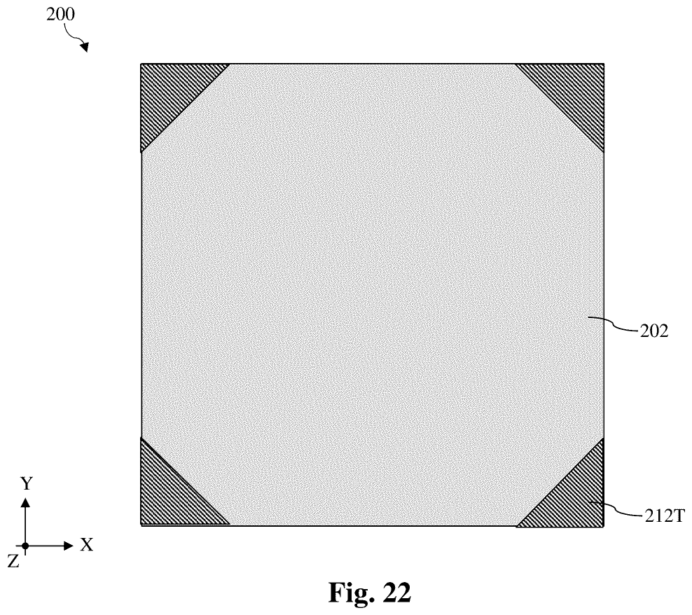

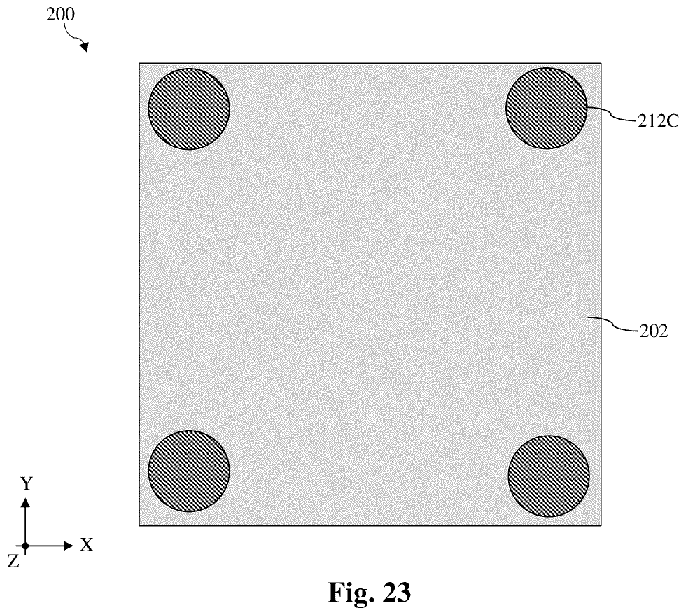

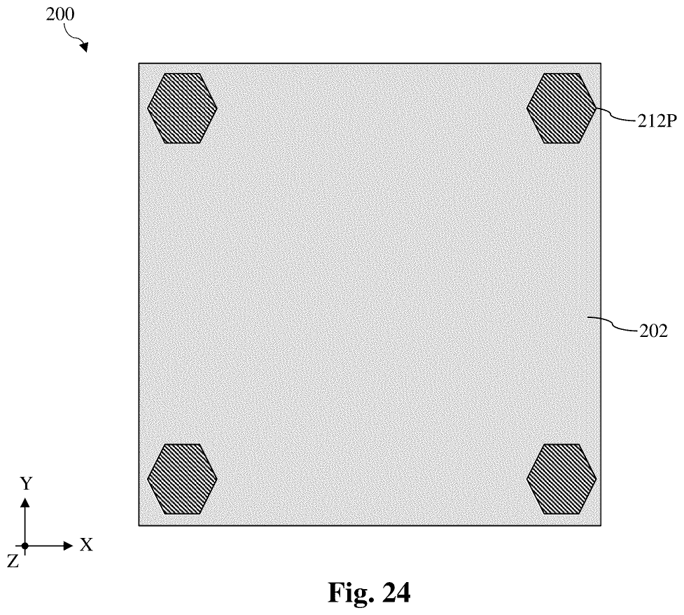

FIGS. 21-24 illustrate alternative embodiments where the peripheral metal pads 212 include different shapes due to shapes of the peripheral opening 205 of the patterned mask. FIG. 21 illustrates a ring-shaped cushion pad 212R that has a top surface coplanar with the substrate 202. The ring-shaped cushion pad 212R goes continuously and completely around a perimeter of the die area 200. That is, an edge of the ring-shape cushion pad 212R and an edge of the die area 200 may be similar. FIG. 22 illustrates four (4) triangular cushion pads 212T disposed at four (4) corners of the die area 200. The four (4) triangular cushion pads 212T have top surfaces coplanar with the back side 202B of the substrate 202. In some embodiments, in a top view, each of the four (4) triangular cushion pads 212T has a shape of a right-angled triangle with two legs (i.e. catheti). Each of the legs may have a length similar to the second edge dimension D2 described above. FIG. 23 illustrates four (4) circular cushion pads 212C disposed at four (4) corners of the die area 200. The four (4) circular cushion pads 212C have top surfaces coplanar with the back side 202B of the substrate 202. In some embodiments, in a top view, each of the four (4) circular cushion pads 212C has a shape of a circle, an oval or a racetrack. A diameter, a major axis, or a length of the circular cushion pad 212C may be similar to the second edge dimension D2 described above. FIG. 24 illustrates four (4) polygonal cushion pads 212P disposed at four (4) corners of the die area 200. The four (4) polygonal cushion pads 212P have top surfaces coplanar with the back side 202B of the substrate 202. In some embodiments represented in FIG. 24, in a top view, each of the four (4) polygonal cushion pads 212P has a shape of a hexagon. In some alternative embodiments not explicitly shown in the figures, each of the four (4) polygonal cushion pads 212P has a shape of a pentagon or an octagon. A length or a width of the polygonal cushion pad 212P may be similar to the second edge dimension D2 described above.

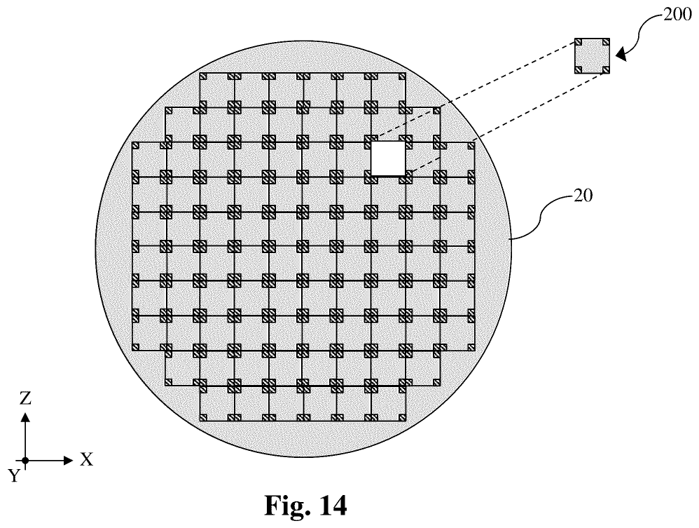

Referring to FIGS. 1 and 14, method 100 includes a block 116 where a singulation process is performed to cut a die 200 out of the die area 200 of the wafer 20. The operations at block 102-114 described above are performed while the die area 200 is an area of the wafer 20 and the wafer 20 goes through these operations undivided and in one piece. At block 116, a singulation process is performed to the wafer 20 to cut the die areas 200 out of the wafer 20 to form a die 200. The die 200 may be a system-on-chip (SoC) die, a logic die, or an application specific integrated circuit (ASIC) die. It is noted that the cushion pads 212, regardless of their shapes, are disposed over a vacant area of the substrate 202. For that reason, the cushion pads 212 are not in contact with any contact features and are therefore, electrically floating. Because the cushion pads 212 are formed of metals, their coefficient of thermal expansion (CTE) and thermal conductivities are much greater than the substrate 202. The high CTE allows the cushion pads 212 to control or counter warpage of the die 200 during a subsequent bonding process. By controlling the warpage, the cushion pads 212 prevent non-bond situation with a die, dies, or a heat sink disposed over or below the die 200. The high thermal conductivities of the cushion pads 212 improve thermal conduction to a die or a heat sink to be bonded to the back side 212B of the substrate.

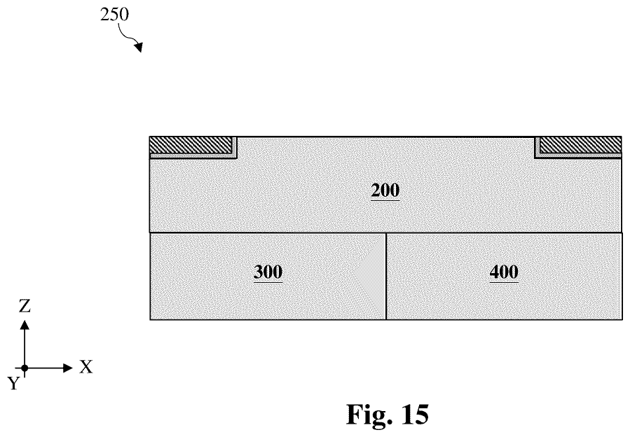

Referring to FIGS. 1 and 15, method 100 includes a block 118 where the die 200 is bonded to at least one other die to form a first package component 250. While not explicitly shown in the figures, the die 200 may include contact pads on both sides and may include through-substrate-vias (TSVs) extending through the substrate 202 to provide electrical connection through the entire thickness of the die 200. In some embodiments illustrated in FIG. 15, the die 200 is bonded to a die 300 and a die 400. Like the die 200, each of the die 300 and the die 400 may be an SoC die, a logic die or an ASIC die. In some embodiments, the die 200 is bonded onto the die 300 and the die 400 using direct bonding. When the die 200 is bonded to die 300 and die 400 using direct bonding, bonding contact pads on the die 200 is vertically aligned with bonding contact pads on the die 300 and the die 400. The bonding contact pads are surrounded by a dielectric layer. In an example direct bonding process, after surfaces of the dielectric layer and the bonding contact pads are cleaned and treated with plasma, the dies are heated and bonding contact pads are aligned to form metal-to-metal and dielectric-to-dielectric bonding. A molding material may be disposed laterally between the die 300 and the die 400. The stacked structure of the die 200, the die 300 and the die 400 may be collectively referred to as a first package component 250.

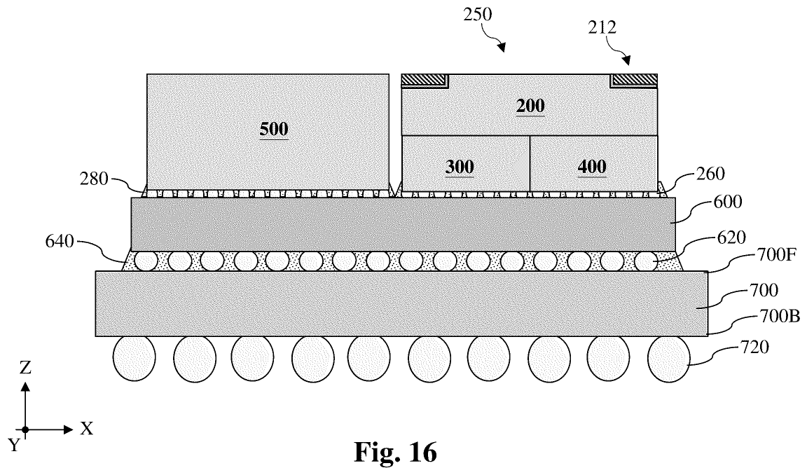

Referring to FIGS. 1 and 16, method 100 includes a block 120 where the first package component 250 is bonded to a package substrate 700. In some embodiments represented in FIG. 16, block 120 first bonds the first package component 250 to an interposer 600 by way of first connection features 260. In some embodiments, the first connection features 260 may include micro-bumps, metal pillars, or solder features. The space between the interposer 600 and first package component 250 may be filled with a first underfill 280. The interposer 600 may include a semiconductor material or glass. In one embodiment, the interposer 600 includes silicon (Si). In some alternative embodiments, the interposer 600 includes silicon germanium (SiGe) or silicon carbon (SiC). In the depicted embodiments, a memory package component 500 is also bonded to the interposer 600. In some implementations, the memory package component 500 may include a high bandwidth memory (HBM) component. The memory package component 500 may include a vertical stack of a controller die and a plurality of memory dies. Each of the plurality of memory dies may be a dynamic random-access memory (DRAM) die and the controller die is configured to read from and write into the plurality of memory dies. Like the package component 250, the memory package component 500 may be bonded to the interposer 600 by way of connection features similar to the first connection features 260. The space between the interposer 600 and the memory package component 500 may be filled with an underfill similar to the first underfill 280. In some instances, the first underfill 280 may include polymer or epoxy.

At block 120, the interposer 600 is bonded to the package substrate 700 by way of second connection features 620. The package substrate 700 includes a frontside surface 700F and a backside surface 700B. In FIG. 16, the interposer 600 is bonded to the frontside surface 700F of the package substrate 700. Third connection features 720 are deposited over the backside surface 700B of the package substrate 700. In some embodiments, the second connection features 620 may include controlled collapse chip connection (C4) bumps or other solder bumps. The third connection features 720 may include solder features or solder balls and may include a ball grid array (BGA). In some embodiments, the package substrate 700 may include a printed circuit board (PCB) or the like. While not explicitly shown in the features, the package substrate 700 may include through-substrate vias (TSVs) or through hole connectors that extend from the frontside surface 700F to the backside surface 700B. Additionally, in order to electrically couple to the interposer 600, the package substrate 700 may include a plurality of contact pads over the frontside surface 700F. In order to electrically couple to the third connection features 720 over the backside surface 700B, the package substrate 700 may also include a plurality of contact pads or under bump metallization (UBM) features over the backside surface 700B. The space between the interposer 600 and the package substrate 700 is filled with a second underfill 640. Like the first underfill 280, the second underfill 640 may include polymer or epoxy. While not explicitly shown in FIG. 16, molding material may be deposited around the sidewalls of the interposer 600, sidewalls of the memory package component 500, and sidewalls of the package component 250.

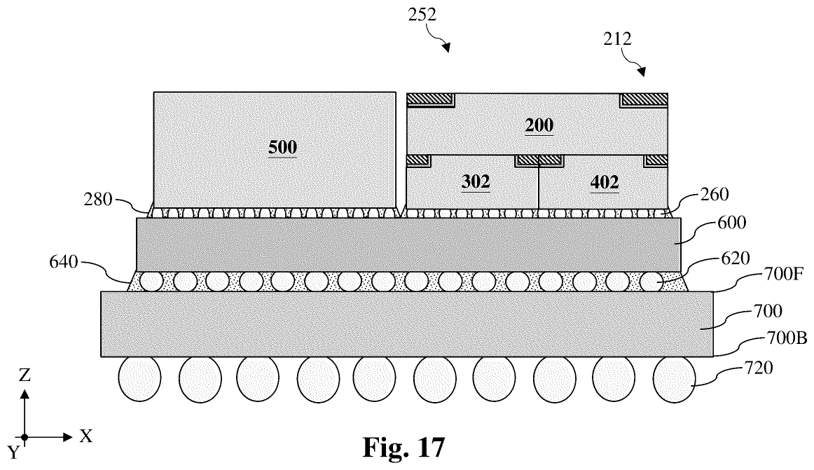

FIGS. 17-20 illustrate alternative multi-die package structures that may be similarly benefited from the cushion pads 212 formed using a method similar to method 100 described above.

Reference is first made to FIG. 17. FIG. 17 illustrates a second package component 252. Instead of being bonded to the dies 300 and 400 that do not have cushion pads 212, the die 200 is bonded to dies 302 and 402. In the embodiments represented in FIG. 17, each of the dies 302 and 402 includes cushion pads similar to the cushion pads 212 on the die 200. It should be understood that the cushion pads on the dies 302 and 402 may be fabricated by following method 100 described above. The die 200, die 302 and die 402 are stacked and bonded together to form the second package component 252. In the multi-die package structure shown in FIG. 17, the second package component 252 are bonded to the interposer 600 along with the memory package component 500 by way of the first connection features 260. The interposer 600 is bonded to the package substrate 700 using the second connection features 620. The package substrate 700 includes third connection features 720 on the backside surface 700B such that the package substrate 700 may be further bonded to other structures. The cushion pads 212 shown in FIG. 17 may include rectangular cushion pads 212 (shown in FIG. 13), ring-shaped cushion pads 212R (shown in FIG. 21), triangular cushion pads 212T (shown in FIG. 22), circular cushion pads 212C (shown in FIG. 23), or polygonal cushion pads 212P (shown in FIG. 24).

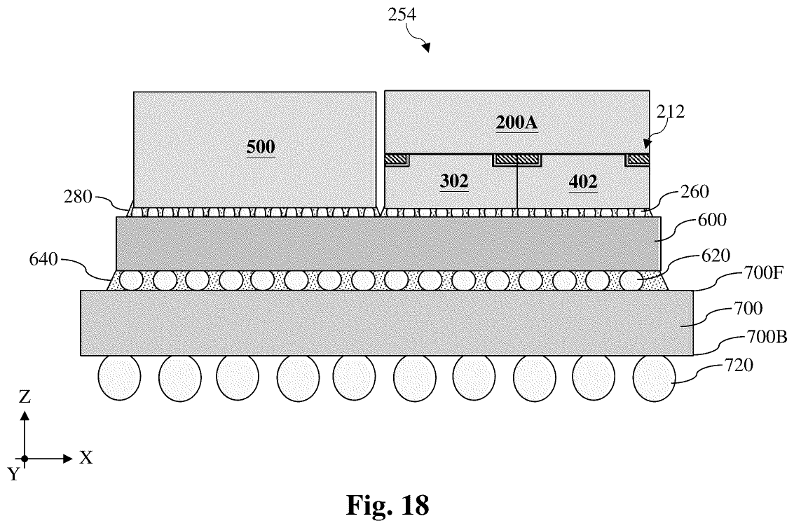

Reference is then made to FIG. 18. FIG. 18 illustrates a third package component 254. In FIG. 18, what is bonded to dies 302 and 402 is a die 200A that does not have any cushion pads 212. Each of the dies 302 and 402 includes cushion pads similar to the cushion pads 212 on the die 200. It should be understood that the cushion pads on the dies 302 and 402 may be fabricated by following method 100 described above. The die 200A, die 302 and die 402 are stacked and bonded together to form the third package component 254. In the multi-die package structure shown in FIG. 18, the third package component 254 is bonded to the interposer 600 along with the memory package component 500 by way of the first connection features 260. The interposer 600 is bonded to the package substrate 700 using the second connection features 620. The package substrate 700 includes third connection features 720 on the backside surface 700B such that the package substrate 700 may be further bonded to other structures. The cushion pads 212 shown in FIG. 18 may rectangular cushion pads 212 (shown in FIG. 13), ring-shaped cushion pads 212R (shown in FIG. 21), triangular cushion pads 212T (shown in FIG. 22), circular cushion pads 212C (shown in FIG. 23), or polygonal cushion pads 212P (shown in FIG. 24).

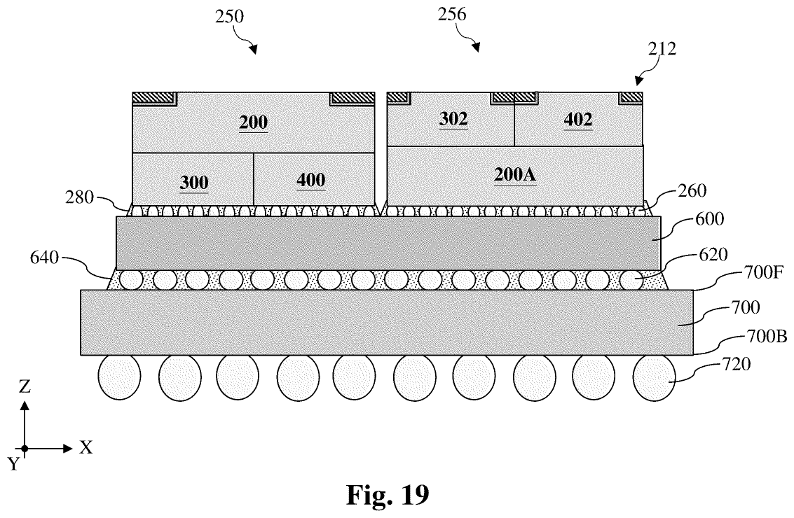

Reference is now made to FIG. 19. FIG. 19 illustrates a fourth package component 256 alongside a package component 250. The fourth package component 256 includes dies 302 and 402 bonded on the die 200A that is free of any cushion pads 212. Instead of having the die 200A on top of the dies 302 and 402, the die 200A is disposed below the dies 302 and 402. Each of the dies 302 and 402 includes cushion pads similar to the cushion pads 212 on the die 200. It should be understood that the cushion pads on the dies 302 and 402 may be fabricated by following method 100 described above. The die 302, die 402, and die 200A are stacked and bonded together to form the fourth package component 256. In the multi-die package structure shown in FIG. 19, the fourth package component 256 are bonded to the interposer 600 along with a package component 250 by way of the first connection features 260. The interposer 600 is bonded to the package substrate 700 using the second connection features 620. The package substrate 700 includes third connection features 720 on the backside surface 700B such that the package substrate 700 may be further bonded to other structures. The cushion pads 212 shown in FIG. 19 may rectangular cushion pads 212 (shown in FIG. 13), ring-shaped cushion pads 212R (shown in FIG. 21), triangular cushion pads 212T (shown in FIG. 22), circular cushion pads 212C (shown in FIG. 23), or polygonal cushion pads 212P (shown in FIG. 24).

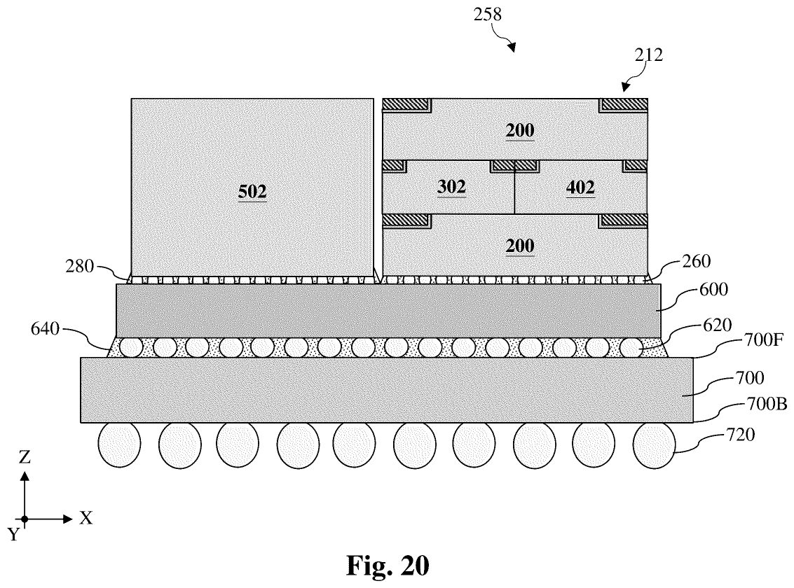

Reference is then made to FIG. 20. FIG. 20 illustrates a fifth package component 258. In FIG. 20, the fifth package component 258 includes two dies 200, the die 302 and the die 402. The dies 302 and 402 are placed side-by-side and bonded to one of the two dies 200. The other of the two dies 200 is bonded over the dies 302 and 402. All of the dies in the fifth package component 258 include cushion pads 212. In the multi-die package structure shown in FIG. 20, the fifth package component 258 are bonded to the interposer 600 along with an alternative memory package component 502 by way of the first connection features 260. The alternative memory package component 502 may include more memory dies than the memory package component 500. The interposer 600 is bonded to the package substrate 700 using the second connection features 620. The package substrate 700 includes third connection features 720 on the backside surface 700B such that the package substrate 700 may be further bonded to other structures. The cushion pads 212 shown in FIG. 20 may rectangular cushion pads 212 (shown in FIG. 13), ring-shaped cushion pads 212R (shown in FIG. 21), triangular cushion pads 212T (shown in FIG. 22), circular cushion pads 212C (shown in FIG. 23), or polygonal cushion pads 212P (shown in FIG. 24).

The present disclosure provides many embodiments. In one aspect, the present disclosure provides a semiconductor package. The semiconductor package includes an interposer, a component mounted on the interposer and including a first die and a second die disposed over the first die and including a surface away from the first die. The second die includes a metal pad. A top surface of the metal pad is coplanar with the surface. The metal pad is electrically floating.

In some embodiments, the semiconductor package further includes a high bandwidth memory (HBM) stack mounted on the interposer. In some embodiments, the metal pad is spaced apart from the second die by a seed layer. In some embodiments, the seed layer includes titanium. In some implementations, the metal pad includes aluminum (Al), copper (Cu), or aluminum-copper (AlCu). In some embodiments, the surface of the second die is rectangular in shape. The metal pad is one of four (4) metal pads disposed at four (4) corners of the second die. In some embodiments, each of the four (4) metal pads includes a rectangular shape, a triangular shape, a circulator shape, or a polygonal shape. In some embodiments, the surface of the second die includes semiconductor or a dielectric material.

In another aspect, the present disclosure provides a package structure. The package structure includes an interposer, and a component mounted on the interposer and including a first die and a second die disposed alongside the first die, a third die disposed over the first die and the second die. The third die includes a rectangular surface away from the first die and the second die. The third die includes four (4) metal pads disposed at four (4) corners of the third die. Top surface of the four (4) metal pads are coplanar with the rectangular surface. The four (4) metal pads are electrically floating.

In some embodiments, each of the four (4) metal pads includes a seed layer and a metal layer disposed on the seed layer. In some embodiments, the seed layer includes titanium (Ti) and the metal layer includes aluminum (Al), copper (Cu), or aluminum-copper (AlCu). In some implementations, each of the four (4) metal pads includes a rectangular shape, a triangular shape, a circulator shape, or a polygonal shape. In some embodiments, the four (4) metal pads are of the same dimensions. In some embodiments, the package structure further includes a high bandwidth memory (HBM) stack mounted on the interposer. In some embodiments, the third die includes a semiconductor substrate and the semiconductor substrate includes a first thickness. Each of the four (4) metal pads includes a second thickness and a ratio of the first thickness to the second thickness is between about 20 and about 100.

In still another aspect, the present disclosure provides a method. The method includes forming a patterned mask over a die area on a wafer, the patterned mask exposing a peripheral region of the die area, etching the die area using the patterned mask to form a peripheral recess, depositing a seed layer over the die area and the patterned mask, after the depositing of the seed layer, removing the patterned mask, after the removing of the patterned mask, depositing a metal layer over the seed layer, planarizing the wafer to form a peripheral metal pad in the peripheral recess, singulating the die area as a die, bonding the die to at least another die to form a component, and mounting the component on a package substrate.

In some embodiments, the package substrate includes an interposer. In some embodiments, the depositing of the seed layer includes depositing titanium by sputtering. In some implementations, the seed layer includes a thickness between about 1000 Å and about 3000 Å. In some instances, the depositing of the metal layer includes use of electrochemical plating.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
an interposer bonded to the package substrate; and
a package component mounted on the interposer and comprising:
a first die, and
a second die disposed over the first die and comprising a substrate facing away from the first die,
wherein the second die comprises a cushion pad disposed along all edges of a top surface of the substrate.

2. The package structure of claim 1, wherein a top surface of the cushion pad and the top surface of the substrate are coplanar.

3. The package structure of claim 1, wherein the cushion pad is electrically floating.

4. The package structure of claim 1, wherein the substrate comprises silicon (Si), germanium (SiGe), silicon carbide (SiC), silicon germanium (SiGe), or diamond.

5. The package structure of claim 1, wherein the cushion pad comprises:
a seed layer interfacing the substrate; and
a metal layer over the seed layer and spaced apart from the substrate by the seed layer.

6. The package structure of claim 5,
wherein the seed layer comprises titanium, copper, or a combination thereof,
wherein the metal layer comprises aluminum (Al), copper (Cu), or aluminum-copper (AlCu).

7. The package structure of claim 5, wherein a thickness of the seed layer is between about 1000 Å and about 3000 Å.

8. The package structure of claim 1,
wherein the substrate comprises a first thickness,
wherein the cushion pad comprises a second thickness,
wherein a ratio of the second thickness to the first thickness is between about 1/100 and about 1/20.

9. The package structure of claim 8, wherein the second thickness is between about 3 μm and about 15 μm.

10. The package structure of claim 1,
wherein the interposer comprises a semiconductor material or glass, and
wherein the package substrate comprises a printed circuit board (PCB).

11. A package structure, comprising:
a printed circuit board (PCB);
a silicon interposer bonded to the PCB; and
a package component mounted on the silicon interposer and comprising:
a first die, and
a second die disposed over the first die and comprising a substrate facing away from the first die,
wherein the second die comprises a conductive cushion pad that extends along all edges of the substrate,
wherein the conductive cushion pad is electrically floating.

12. The package structure of claim 11, wherein a top surface of the conductive cushion pad and a top surface of the substrate are coplanar.

13. The package structure of claim 11, wherein the substrate comprises silicon (Si), germanium (SiGe), silicon carbide (SiC), silicon germanium (SiGe), or diamond.

14. The package structure of claim 13,
wherein the substrate comprises a first thickness,
wherein the conductive cushion pad comprises a second thickness,
wherein a ratio of the second thickness to the first thickness is between about 1/100 and about 1/20.

15. The package structure of claim 11 wherein the conductive cushion pad comprises:
a seed layer interfacing the substrate; and
a metal layer over the seed layer and spaced apart from the substrate by the seed layer.

16. The package structure of claim 15,
wherein the seed layer comprises titanium, copper, or a combination thereof,
wherein the metal layer comprises aluminum (Al), copper (Cu), or aluminum-copper (AlCu).

17. A package structure, comprising:
a package substrate;
an interposer bonded to the package substrate by way of controlled collapse chip connection (C4) bumps; and
a package component mounted on the interposer by way of micro-bumps and comprising:
a first die, and
a second die disposed over the first die and comprising a substrate facing away from the first die,
wherein the second die comprises a cushion pad disposed along all edges of a top surface of the substrate,
wherein a top surface of the cushion pad and the top surface of the substrate are coplanar,
wherein the substrate comprises a first thickness,
wherein the cushion pad comprises a second thickness,
wherein a ratio of the second thickness to the first thickness is between about 1/100 and about 1/20.

18. The package structure of claim 17 wherein the cushion pad comprises:
a seed layer interfacing the substrate; and
a metal layer over the seed layer and spaced apart from the substrate by the seed layer.

19. The package structure of claim 18,
wherein the seed layer comprises titanium, copper, or a combination thereof,
wherein the metal layer comprises aluminum (Al), copper (Cu), or aluminum-copper (AlCu).

20. The package structure of claim 19, wherein the cushion pad is electrically floating.
